(19) United States
(12) Patent Application Publication
(10) Pub. No.: US 2014/0109966 A1
(43) Pub. Date: Apr. 24, 2014

(54) BIFACIAL THIN FILM SOLAR CELL FABRICATED BY PASTE COATING METHOD

(71) Applicant: KOREA INSTITUTE OF SCIENCE AND TECHNOLOGY, (US)

(72) Inventors: Byoung Koun MIN, Seoul (KR); Doh-Kwon LEE, Seoul (KR); Sung-Hwan MOON, Daegu (KR)

(73) Assignee: KOREA INSTITUTE OF SCIENCE AND TECHNOLOGY, Seoul (KR)

(21) Appl. No.: 13/721,424

(22) Filed: Dec. 20, 2012

(30) Foreign Application Priority Data
Oct. 24, 2012 (KR) 10-2012-0118195

(51) Int. Cl. H01L 31/18

(52) U.S. Cl. CPC H01L 31/18
USPC 136/262; 438/95; 136/252; 136/263

(57) ABSTRACT

Disclosed is a bifacial thin film solar cell, particularly a bifacial CuInGaS, thin film solar cell, fabricated by a paste coating method. According to several embodiments, the bifacial thin film solar cell results in a higher conversion efficiency of bifacial illumination than the simple sum of the efficiencies of upper and lower side illumination only, unlike those previously reported. The bifacial thin film solar cell exhibits many other effects described in the specification.

### CROSS-REFERENCE TO RELATED APPLICATIONS

This application claims priority under 35 U.S.C. §119 to Korean Patent Application No. 10-2012-0118195 filed on Oct. 24, 2012, in the Korean Intellectual Property Office, the disclosure of which is incorporated herein by reference in its entirety.

### BACKGROUND OF THE INVENTION

1. Field of the Invention

The present invention relates to a bifacial inorganic thin film solar cell, particularly a bifacial CuInₓGa₁₋ₓS_{y}Se_{2-y} thin film solar cell, fabricated by a paste coating method.

2. Description of the Related Art

Solar cells can produce electricity directly from sunlight, which is a clean and safe energy source. For this reason, solar cells have attracted considerable attention as the most promising future candidates for energy production. Various kinds of inorganic and organic semiconductors are applied to the fabrication of solar cells. Representative examples of solar cells that have been commercially successful to date include silicon solar cells using silicon (Si) as a main material, and CIGS thin film solar cells. Silicon solar cells have the advantage of high photoelectric conversion efficiency but suffer from high fabrication costs. Under such circumstances, thin film solar cells using compound semiconductors that can be formed into thinner films are of growing interest as potential replacements for silicon solar cells.

Chalcopyrite compound thin film solar cells in which CuInₓGa₁₋ₓS_{y}Se_{2-y} (CIGS) film is used as an absorber layer have been considered the most promising alternative to crystalline silicon solar cells. In general, CIGS thin film solar cells have a typical device configuration of ZnO:Al/i-ZnO/CdS/CIGS/Mo-coated soda-lime glass, namely, opaque substrate-type. In this architecture, sunlight can transmit from only the front side because an opaque Mo layer blocks light introduction from the rear side. However, sunlight is irradiated at variable angles depending on time of day, and a significant portion of the light is reflected by the ground or surrounding structures, leaving the possibility of absorption through the rear side of the solar cell. The reflected light is available by thin film solar cells using transparent glass substrates that can absorb light entering the rear side. Such solar cells are called bifacial solar cells. In addition, fabrication of an absorber layer on a transparent semiconductor substrate is an important issue for achieving multi junction (tandem) solar cell devices and solar windows as well as efficient use of light.

Bifacial CIGS thin film solar cells using transparent glass substrates have already been reported, but all these are associated with the application of conventional vacuum based deposition methods to the preparation of CIGS thin film absorber layers as the most important elements thereof. Methods for producing CIGS thin films by low cost chemical processes instead of using vacuum systems are currently under study for the fabrication of inexpensive CIGS thin film solar cells. Particularly, methods for producing CIGS thin films by printing processes are known as the most promising in terms of processing speed, processing cost and large-area production. Solution processed bifacial inorganic thin film solar cells have never been, to our knowledge, reported before. Furthermore, no study on the inherent characteristics of solution processed bifacial thin film solar cells has been, to our knowledge, reported.

### SUMMARY OF THE INVENTION

Several embodiments of the present invention are intended to provide a bifacial thin film solar cell based on a low cost solution process that results in a higher power conversion efficiency of bifacial illumination than the simple sum of the efficiencies of front and rear side illumination only, implying the presence of synergistic effects in the bifacial solar cell configuration, unlike those reported in conventional bifacial thin film solar cells based on vacuum deposition.

According to an aspect of the present invention, there is provided a thin film solar cell including (a) a transparent conducting substrate, (b) a solution processed absorber layer formed on the transparent conducting substrate, and (c) a buffer layer, a window layer, and a metal electrode formed on the absorber layer.

As mentioned above, the bifacial thin film solar cell of the present invention results in a higher power conversion efficiency of bifacial illumination than the simple sum of the efficiencies of front and rear side illumination only, unlike those reported in conventional bifacial thin film solar cells based on vacuum deposition. The thin film solar cell of the present invention exhibits many other effects, which will be described below.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 shows cross-sectional SEM images ((a)-(c)) of three different thick CIGS films grown on ITO glass substrates. (a): 400 nm, (b): 800 nm, and (c): 1200 nm. Arrows indicate the CIGS film thickness;

FIG. 2 shows XRD patterns of three different thick CIGS films grown on ITO glass substrates;

FIG. 3 show J-V characteristics of CIGS solar cell devices with different levels of film thickness for front (a) and rear side (b) illumination under 1 Sun conditions;

FIG. 4 shows IPCE spectra of solar cell devices with different levels of CIGS film thickness for front (a) and rear side (b) illumination only;

FIG. 5 shows solar cell efficiencies of solar cell devices with different levels of CIGS film thickness for front and rear side illumination only, numerical sum of front and rear side illumination only, and bifacial illumination under 1 Sun conditions. Arrows indicate extra increase of efficiencies due to bifacial illumination;

FIG. 6 shows extra gains of solar cell efficiencies due to bifacial illumination with respect to irradiated light intensities. Light intensity in X-axis is presented by the percentage of Jsc with respect to that of 1 Sun irradiation, which was measured by a standard Si solar cell; and

FIG. 7 shows (a) J-V characteristics of a bifacial solar cell device with an 800 nm thick CIGS film and (b) a comparison of efficiencies of the solar cell device irradiated on front and rear side only, numerical sum of front and rear side illumination only, and bifacial illumination under outdoor conditions. The arrow indicates extra increase of efficiency due to bifacial illumination.

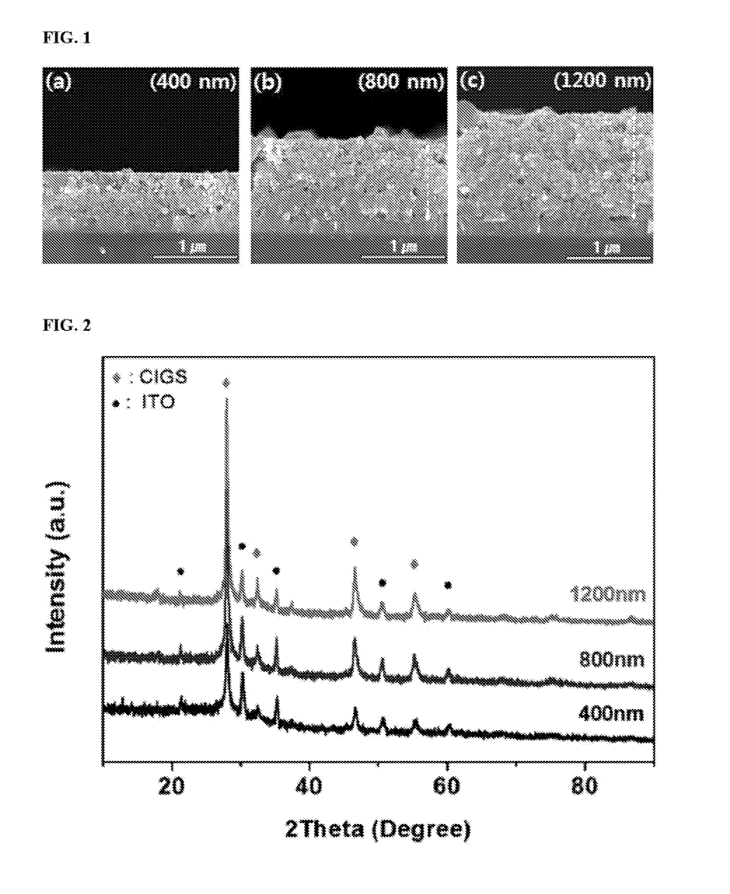

### DETAILED DESCRIPTION OF THE INVENTION

The present invention will now be described in detail.

In an aspect, the present invention provides a thin film solar cell including (a) a transparent conducting substrate, (b) a solution processed absorber layer formed on the transparent conducting substrate, and (c) a buffer layer, a window layer, and a metal electrode formed on the absorber layer.

Due to the presence of the absorber layer formed on the transparent conducting substrate, the bifacial thin film solar cell of the present invention can efficiently use sunlight irradiated on both sides thereof. Particularly, the formation of the absorber layer by a solution processing method enables the fabrication of the bifacial thin film solar cell by a low cost way. The formation of the absorber layer by a solution processing method is particularly preferred in that the bifacial illumination results in an extra increase of the power conversion efficiency compared to the simple sum of the efficiencies of front and rear side illumination only, which will be discussed in detail hereinafter.

The conversion efficiencies of the bifacial thin film solar cell for front and rear side illumination vary depending on the thin film thickness of the absorber layer. Higher efficiency is exhibited at a larger thickness of the absorber layer for front side illumination, while the highest solar cell efficiency is exhibited at an optimum thickness of the absorber layer for rear side illumination. Therefore, the bifacial solar cell in which sunlight is irradiated on both sides exhibits the highest efficiency at a particular thickness of the absorber layer. Preferably, the overall power conversion efficiency of the bifacial solar cell is highest when the absorber layer is about 800 nm thick. In light of the fact that an absorber layer of a general CIGS thin film solar cell is formed to a thickness of about 2,000 nm on an opaque substrate, the bifacial thin film solar cell of the present invention has the advantage that better effects can be attained despite the use of much smaller amounts of material.

It should be understood that the thickness of the absorber layer used in the bifacial solar cell of the present invention does not indicate the corresponding exact value only and includes approximate values within the permissible range in the art. For example, the 800 nm thick absorber layer means that the absorber layer not only has an average thickness of exactly 800 nm, but also has a thickness in the range of, for example, 800 nm±20%, preferably 800 nm±10%. The above-mentioned effects can be maximized when the approximation range is narrower.

The transparent conducting substrate may be made of at least one material selected from indium tin oxide, fluorine-doped indium tin oxide, glass, graphene, and transparent conducting polymers. A transparent non-conducting substrate coated with at least one material selected from indium tin oxide, fluorine-doped indium tin oxide, glass, and transparent conducting polymers may also be used as the transparent conducting substrate.

In an embodiment of the present invention, the solution processed absorber layer is produced by a method including (a) dissolving a metal precursor and a polymer binder in a solvent to obtain a precursor paste, (b) coating the precursor paste on the transparent conducting substrate, (c) annealing the transparent conducting substrate coated with the precursor paste in air or an oxygen gas atmosphere to obtain a metal oxide thin film, and (d) annealing the metal oxide thin film in a sulfur gas, a selenium gas or a sulfur/selenium mixed gas atmosphere to obtain a sulfurized or selenized metal oxide thin film.

In a further embodiment, the solvent may be selected from water, alcohol, acetone, and mixtures thereof, and the polymer binder may be selected from ethyl cellulose, polyvinyl acetate, palmitic acid, polyethylene glycol, polypropylene glycol, polypropylene carbonate, propylenediol, and mixtures thereof.

In a further embodiment, the metal precursor is preferably a mixture of a Cu precursor, an In precursor and a Ga precursor, and the sulfurized or selenized metal oxide thin film is preferably a CIGS thin film.

In an embodiment of the present invention, the solution processed absorber layer is produced by a method including (a) mixing a first metal precursor, a first organic binder, and a first water-soluble solvent to obtain a first paste, (b) mixing a second metal precursor, a second organic binder, and a second water-soluble solvent to obtain a second paste, (c) coating the first paste on the transparent conducting substrate to form a first paste layer, (d) coating the second paste on the first paste layer to form a second paste layer, (d′) optionally repeatedly coating the pastes (i.e. optionally sequentially forming third, fourth, . . . n-th paste layers by coating), (e) annealing the coated transparent conducting substrate in air or an oxygen atmosphere to obtain a mixed oxide thin film, and (f) annealing the mixed oxide thin film in a sulfur gas, a selenium gas or a sulfur/selenium mixed gas atmosphere to obtain a sulfide or selenide thin film.

The first metal precursor and the second metal precursor, which may be identical to or different from each other, may be each independently a precursor of one or more Group IB metals, a precursor of one or more Group IIIA metals, or a mixture thereof. The precursor of one or more Group IB metals and the precursor of one or more Group IIIA metals may be each independently included in either the first metal precursor or the second metal precursor or both of them.

In a further embodiment of the present invention, the solution processed absorber layer is produced by a method including (a) mixing first metal precursors, a first organic binder, and a first water-soluble solvent to obtain a first paste, (b) mixing second metal precursors, a second organic binder, and a second water-soluble solvent to obtain a second paste, (c) coating the first paste on the transparent conducting substrate to form a first paste layer, (d) coating the second paste on the first paste layer to form a second paste layer, (d′) optionally repeatedly coating the pastes (i.e. optionally sequentially forming third, fourth, . . . n-th paste layers by coating), (e) annealing the coated transparent conducting substrate in air or an oxygen atmosphere to obtain a CIG mixed oxide thin film, and (f) annealing the CIG mixed oxide thin film in a sulfur gas, a selenium gas or a sulfur/selenium mixed gas atmosphere to obtain a CIGS thin film.

The first metal precursors and the second metal precursors, which may be identical to or different from each other, may be each independently two or more kinds of precursors selected from Cu, In and Ga precursors. The Cu, In and Ga precursors may be each independently included in either the first metal precursors or the second metal precursors or both of them.

In another further embodiment, the first water-soluble solvent and the second water-soluble solvent, which may be identical to or different from each other, may be each independently selected from water, alcohol, acetone, and mixtures thereof. The first organic binder and the second organic binder, which may be identical to or different from each other, may be each independently selected from ethyl cellulose, polyvinyl acetate, palmitic acid, polyethylene glycol, polypropylene glycol, polypropylene carbonate, propylenediol, and mixtures thereof.

In an embodiment of the present invention, the viscosity of the first paste is different by 400 to 1,500 cP from that of the second paste. Due to this viscosity difference, the microstructures of the adjacent light-absorbing layers are different enough to improve the performance of the final solar cell.

In a further embodiment, the first and second pastes have viscosities not lower than 700 cP and not higher than 300 cP, respectively, particularly 700 to 1,500 cP and 50 to 300 cp, respectively. Within the viscosity ranges defined above, internal compaction and surface flatness of the light-absorbing layers can be ensured simultaneously.

In another embodiment of the present invention, the first organic binder is preferably (i) ethyl cellulose or (ii) a mixture including 90 to 99.9 parts by weight of ethyl cellulose and 0.1 to 10 parts by weight of polyvinyl acetate, palmitic acid, polyethylene glycol, polypropylene glycol, polypropylene carbonate, propylenediol or a mixture thereof; and the second organic binder is preferably (i) polyvinyl acetate or (ii) a mixture including 90 to 99.9 parts by weight of polyvinyl acetate and 0.1 to 10 parts by weight of ethyl cellulose, palmitic acid, polyethylene glycol, polypropylene glycol, polypropylene carbonate, propylenediol or a mixture thereof. By the constituent organic materials of the binders, internal compaction and surface flatness of the light-absorbing layers can be ensured even when each of the first and second pastes is coated only once.

In another embodiment of the present invention, the ratios of the concentration of the Cu element to the sum of the concentrations of the In and Ga elements in the first and second paste layers are preferably 1:0.9-1.3, most preferably 1:1.2.

The ratio of the concentration of the Ga element to that of the Cu element in the first paste layer is preferably different by 0.1 to 0.9 from the ratio of the concentration of the Ga element to that of the Cu element in the second paste layer. Due to this concentration difference, the concentration distributions of the Ga element in the adjacent light-absorbing layers are different enough to improve the performance of the final solar cell.

In another embodiment of the present invention, the method may further include forming a third paste layer on the second paste layer wherein the ratios of the concentration of the Cu element to the sum of the concentrations of the In and Ga elements in the first, second and third paste layers are preferably 1:0.9-1.3:0.9-1.3. The concentration distributions of the Ga element in the paste layers are preferably adjusted such that the ratios of the concentration of the Ga element to that of the Cu element in the first and third paste layers are greater by 0.1 to 0.9 than the ratio of the concentration of the Ga element to that of the Cu element in the second paste layer. Particularly, when the Ga concentrations in the upper and lower portions are higher than the Ga concentration in the central portion within the range defined above, no recombination of electrons and holes occurs at the interfaces.

In an embodiment of the present invention, steps (e) and (f) may be carried out at temperatures of 250 to ° C. 550° C. and 400 to 600° C., respectively, the sulfur gas atmosphere may be a H₂S gas or S vapor atmosphere, and the selenium gas atmosphere may be a H₂Se gas or Se vapor atmosphere.

In a further embodiment of the present invention, step (c) may further include (c−1) drying the first paste coated on the transparent conducting substrate. The first paste is preferably dried in an air atmosphere at 100 to 300° C. The drying markedly improves the processing speed and enables the production of the thin film on a large area.

In another embodiment of the present invention, step (d) may further include (d−1) drying the second paste coated on the first paste layer. The second paste is preferably dried in an air atmosphere at 100 to 300° C. The drying further markedly improves the processing speed and enables the production of the thin film on a large area.

In an embodiment of the present invention, the Cu precursor may be (i) a hydroxide, nitrate, sulfate, acetate, chloride, acetylacetonate, formate or oxide of Cu, (ii) a hydroxide, nitrate, sulfate, acetate, chloride, acetylacetonate, formate or oxide of a Cu/In or Cu/Ga alloy, or (iii) a mixture thereof.

The In precursor may be (i) a hydroxide, nitrate, sulfate, acetate, chloride, acetylacetonate, formate or oxide of In, (ii) a hydroxide, nitrate, sulfate, acetate, chloride, acetylacetonate, formate or oxide of an In/Cu or In/Ga alloy, or (iii) a mixture thereof.

The Ga precursor may be (i) a hydroxide, nitrate, sulfate, acetate, chloride, acetylacetonate, formate or oxide of Ga, (ii) a hydroxide, nitrate, sulfate, acetate, chloride, acetylacetonate, formate or oxide of a Ga/Cu or Ga/In alloy, or (iii) a mixture thereof.

In a further embodiment of the present invention, (i) the first paste may further include a dispersant selected from α-terpineol, ethylene glycol, thioacetamide, ethylenediamine, and mixtures thereof; (ii) the second paste may further include a dispersant selected from α-terpineol, ethylene glycol, thioacetamide, ethylenediamine, and mixtures thereof; or (iii) each of the first and second pastes may further include a dispersant selected from α-terpineol, ethylene glycol, thioacetamide, ethylenediamine, and mixtures thereof.

In another embodiment of the present invention, the first and second pastes may each independently further include a dopant selected from Na, K, Ni, P, As, Sb, Bi, and mixtures thereof. The dopant may be present in an amount of 1 to 100 parts by weight, based on 100 parts by weight of the first metal precursors and/or the second metal precursors.

In another aspect, the present invention provides a chalcopyrite compound thin film produced by solution processing wherein the concentrations of Ga in the upper and lower portions are higher than the concentration of Ga in the central portion.

In another aspect, the present invention provides a chalcopyrite compound thin film including, as light-absorbing layers, at least two coating layers formed on a transparent conducting substrate wherein the light-absorbing layer positioned relatively close to the transparent conducting substrate has a higher average density than the light-absorbing layer relatively remote from the transparent conducting substrate.

In another aspect, the present invention provides a chalcopyrite compound thin film including, as light-absorbing layers, at least two coating layers formed on a transparent conducting substrate wherein the light-absorbing layer positioned relatively close to the transparent conducting substrate includes, as an organic binder, (i) ethyl cellulose or (ii) a mixture including 90 to 99.9 parts by weight of ethyl cellulose and 0.1 to 10 parts by weight of polyvinyl acetate, palmitic acid, polyethylene glycol, polypropylene glycol, polypropylene carbonate, propylenediol or a mixture thereof and the light-absorbing layer positioned relatively remote from the transparent conducting substrate includes, as an organic binder, (i) polyvinyl acetate or (ii) a mixture including 90 to 99.9 parts by weight of polyvinyl acetate and 0.1 to 10 parts by weight of ethyl cellulose, palmitic acid, polyethylene glycol, polypropylene glycol, polypropylene carbonate, propylenediol or a mixture thereof.

In yet another aspect, the present invention provides a chalcopyrite compound thin film including, as light-absorbing layers, at least three coating layers formed on a transparent conducting substrate wherein the ratios of the concentration of the Ga element to that of the Cu element in the light-absorbing layer positioned closest to the transparent conducting substrate and the light-absorbing layer remotest from the transparent conducting substrate are greater by 0.1 to 0.9 than the ratio of the concentration of the Ga element to that of the Cu element in the light-absorbing layer positioned between the two other light-absorbing layers.

Although the solution processing method used in the present invention has been described with reference to the foregoing embodiments, it is not limited to the embodiments. The solution processing method is intended to include not only the methods mentioned in the above embodiments but also conventional low cost solution coating methods for producing CIS absorber thin film layers using inks of CIS nanoparticles and inks or pastes of CIS precursors.

Hereinafter, a detailed description will be given about the embodiments of the present invention.

To date several studies regarding bifacial CIGS thin film solar cells have been reported. For example, bifacial CIGS solar cells based on tin-doped indium oxide (ITO) glass substrate have been fabricated and showed best efficiencies of 12.6, 7.4, and 20.0% when light is illuminated on front, rear, and both sides, respectively, implying a potential increase of solar cell efficiency due to bifacial configuration. In most studies, however, the conventional vacuum based deposition method was applied to the CIGS absorber layer preparation.

In order to fabricate CIGS thin films more cost effectively, solution based printing methods are more desirable because they have advantages such as low processing capital costs, efficient resource material usage, high throughput, etc. To achieve bifacial CIGS thin film solar cells by a low cost and printable way, a fabrication method similar to that of CIGS thin film on Mo coated glass was applied to the substrate of transparent conducting oxide (ITO) glass. Three CIGS absorber films with different levels of thickness (400, 800, 1200 nm) were prepared in order to investigate the absorber film thickness dependent solar cell performance. In order to mimic outdoor applications of bifacial solar cell devices, both sides of the device were illuminated by two solar simulators. The front side illumination was set at 1 Sun condition, and variable light intensity was used for the rear side illumination (to imitate the weaker light of light reflected by the ground). It was found that there is a synergistic effect due to the bifacial device configuration. This effect was more prominent in devices with thinner CIGS films, which was also confirmed by outdoor testing of the device.

### Example 1

### Fabrication of Solution Processed Bifacial Thin Film Solar Cell

First, a precursor mixture solution was prepared by dissolving Cu(NO₃)₂.xH₂O (99.999%, Alfa Aesar, 1.0 g), In(NO₃)₃.xH₂O (99.99%, Alfa Aesar, 1.12 g), and Ga(NO₃)₃.xH₂O (99.999%, Alfa Aesar, 0.41 g) in methanol (7.0 ml), followed by adding of a methanol solution (7.0 ml) with PVA (Aldrich, 1.0 g). After the mixture solution was stirred for 30 min, a paste suitable for spin coating was prepared. The paste was spin-casted on an ITO glass substrate (Samsung Corning, ˜8Ω/□), and the film was dried on a hotplate at 150° C. for 3 min and subsequently at 250° C. for 7 min. To obtain the desired thickness of the film, the above process was repeated. ˜200 nm thick film was obtained for each deposition.

After coating and drying, the first annealing process, air annealing, was performed at 300° C. for 30 min under ambient conditions. The second annealing process, sulfurization, was carried out at 500° C. for 30 min under H₂S (1%)/N₂ gas environment.

A solar cell device was fabricated according to the substrate type configuration (ZnO:Al/i-ZnO/CdS/CIGS/ITO glass). A 60 nm-thick CdS buffer layer was prepared on the CIGS film by chemical bath deposition (CBD), and i-ZnO (50 nm)/Al-doped n-ZnO (500 nm) was deposited by the radio frequency magnetron sputtering method. A Ni/Al (50/500 nm) grid was prepared as a current collector by thermal evaporation. The active area of the completed cell was 0.44 cm².

Structural characterization of the films was performed using a scanning electron microscope (SEM, FEI, Nova-Nano200) with a 10 kV acceleration voltage and an X-ray diffractometer (XRD, Shimadzu, XRD-6000) with Cu—Kα radiation (λ=0.15406 nm). The film thickness was measured with a surface profiler (Veeco, Dektak 8). Device performances were characterized using a solar simulator (Sun 2000, ABET Technologies, Inc.) and an incident photon-to-current conversion efficiency (IPCE) measurement unit (PV measurement Inc.). During the IPCE measurement, background light (LED, Daejin DMP Co.) was applied.

The resulting films showed film thickness levels of 400, 800, and 1200 nm, as seen in the cross-sectional SEM images (FIG. 2 (a)-(c)). Densely packed film morphologies with low degree of porosity were observed in the three different sizes of CIGS films. The crystal structures on the XRD patterns depending on the film thickness were not substantially different, showing peaks at 28.0° 2θ, with weak peaks at 32.5°, 46.6°, and 55.3° 2θ. Only peak intensity changes were observed with respect to the film thickness, as can be seen in FIG. 2. The most intense peak, at 28.0° 2θ, indicates the polycrystalline CIGS with a (112) orientation. The other prominent peaks correspond to the (204)/(220) and (116)/(312) crystallographic planes. The presence of these peaks clearly indicates the polycrystalline chalcopyrite structure of CIGS, which is in good agreement with a JCPDS reference (PDF #27-0159), as well as with other reported values.

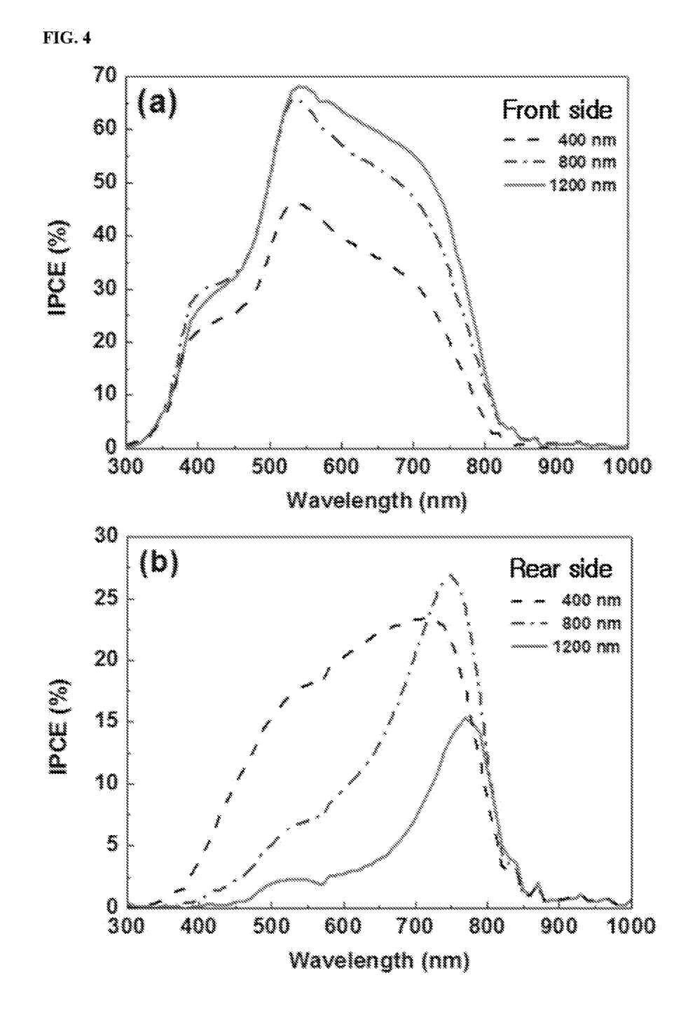

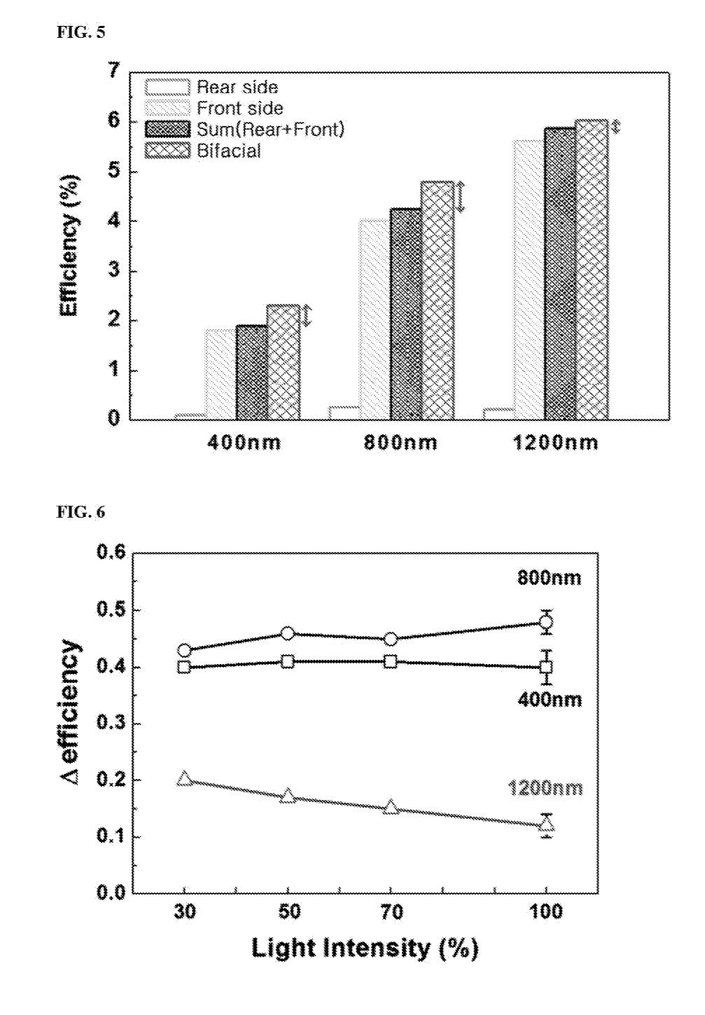

Bifacial solar cell devices were constructed using the CIGS thin films of three different thickness based on substrate-type configuration (ZnO:Al/i-ZnO/CdS/CIGS/ITO glass). General deposition recipes were also applied for a CdS buffer layer (chemical bath deposition) and a ZnO window layer (sputtering deposition). FIG. 4(a) shows the current density-voltage (J-V) characteristics of the solar cell devices that were irradiated from the front side (ZnO face). Both open circuit voltage (Voc) and short circuit current density (Jsc) were found to increase as the film thickness increased (see Table 1). The highest power conversion efficiency, therefore, was obtained by the device with a 1200 nm thick CIGS film, which showed the best power conversion efficiency of 5.61%. On the other hand, for rear side illumination, different J-V behaviors were seen in which the highest efficiency was found in the device with the 800 nm thick CIGS film (1.01%) (FIG. 4(b)).

TABLE 1
Solar cell performance results of bifacial solar cell
devices with different levels of CIGS film thickness

| CIGS film | Illumination | | J_{sc} | | |
|---|---|---|---|---|---|
| thickness(nm) | side | V_{oc} (V) | (mA/cm²) | FF (%) | Eff. (%) |
| 400 | Bifacial | 0.516 | 13.2 | 44.7 | 3.03 |
| | Front only | 0.495 | 8.86 | 40.8 | 1.70 |
| | Rear only | 0.458 | 3.81 | 42.5 | 0.74 |
| 800 | Bifacial | 0.624 | 19.9 | 43.8 | 5.45 |
| | Front only | 0.634 | 15.1 | 41.5 | 3.98 |
| | Rear only | 0.557 | 3.60 | 50.3 | 1.01 |
| 1200 | Bifacial | 0.665 | 17.6 | 53.9 | 6.37 |
| | Front only | 0.680 | 15.5 | 54.1 | 5.61 |
| | Rear only | 0.580 | 1.86 | 61.7 | 0.62 |

The reason why the solar cell device with the thickest film resulted in the highest efficiency for front side illumination is that the most efficient light absorption occurred in the film. However, for rear side illumination, photo-generated electrons and holes in the thicker film have to travel a much longer distance before they arrive at the junction formed at the interface between the CdS buffer layer and the CIGS absorber layer, leading to higher recombination probability. This recombination causes loss of the electrons and holes and results in a low efficiency of the thicker film.

This loss was elucidated in the IPCE data, as can be seen in FIG. 4. The IPCE under front side illumination (FIG. 4(a)) shows an overall increase in intensity with increasing CIGS film thickness in the entire wavelength regime. A closer look, however, reveals that the QE in the range from 370 to 450 nm already saturates for the device with 800 nm thick CIGS, while increasing further in the range of 550 to 800 nm up to 1200 nm thick CIGS. The result is explained by the fact that the photon with a longer wavelength has a higher penetration depth.

On the other hand, the IPCE under rear side illumination (FIG. 4(b)) exhibits quite different features; the highest QE occurs at the wavelength in the range of 700 to 800 nm depending on the CIGS thickness. Moreover, for the shorter wavelength, the QE drastically decreases with increasing the film thickness. Provided that the diffusion length of photo-generated electron is less than the film thickness in CIGS by solution coating method, the electrons generated near CIGS/ITO interface cannot be collected to contribute to the photocurrent. Therefore, the thicker the CIGS film is, the less the collection efficiency is for electron, as indicated by the decrease of QE in the short wavelength regime.

Furthermore, this collection loss (ηc<1) due to recombination becomes more pronounced as the penetration depth (or wavelength) of the photon decreases. Photons with higher penetration depth, i.e., longer wavelength may excite the electronic carriers near CIGS/CdS interface that can be readily collected by the electric field in the space-charge region, resulting in the highest QE in the longer wavelength regime.

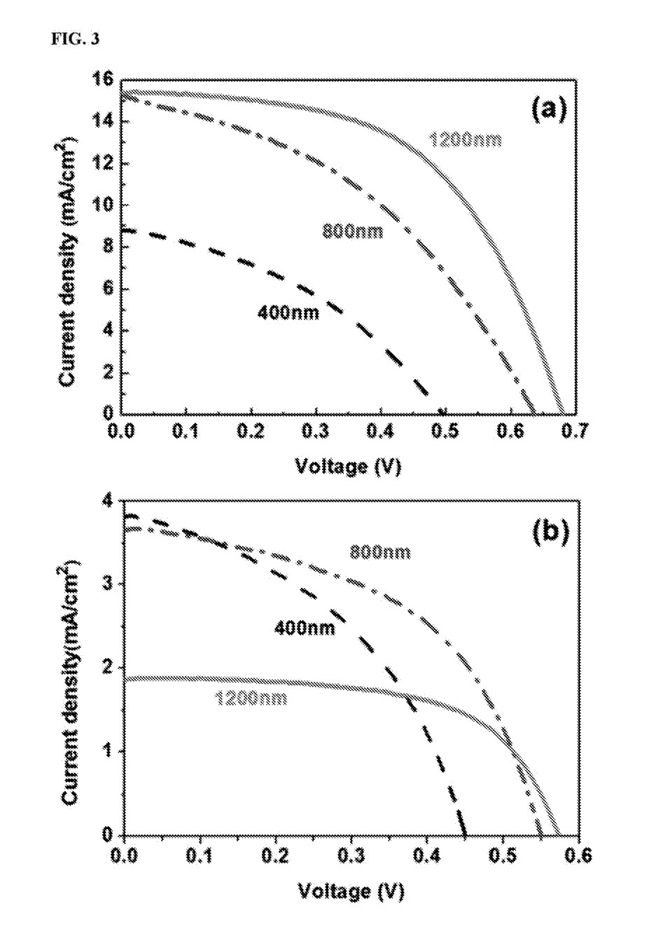

Interestingly, the efficiencies of bifacial illumination are slightly higher than the simple sum of only the front and rear side illumination, implying the presence of synergistic effects in the bifacial solar cell configuration (FIG. 6). As can be seen in FIG. 6, the highest enhancement was observed in the device with the 800 nm thick CIGS film, while the lowest enhancement was found in the device with the 1200 nm thick CIGS film. These trends seem to be similar to those of the power conversion efficiency of the rear side illumination for the same device (FIG. 3(b)).

Finally, to further confirm the efficiency enhancement due to bifacial configuration of solar cell devices, an outdoor test was carried out. The solar cell devices were positioned 30 cm above the ground (a white board). The J-V measurement of the bifacial solar cell devices under outdoor conditions was performed at the almost identical irradiation conditions from the Sun which was confirmed by keeping monitoring photocurrent variation of the standard Si solar cell (positioned right beside the solar cell device for test).

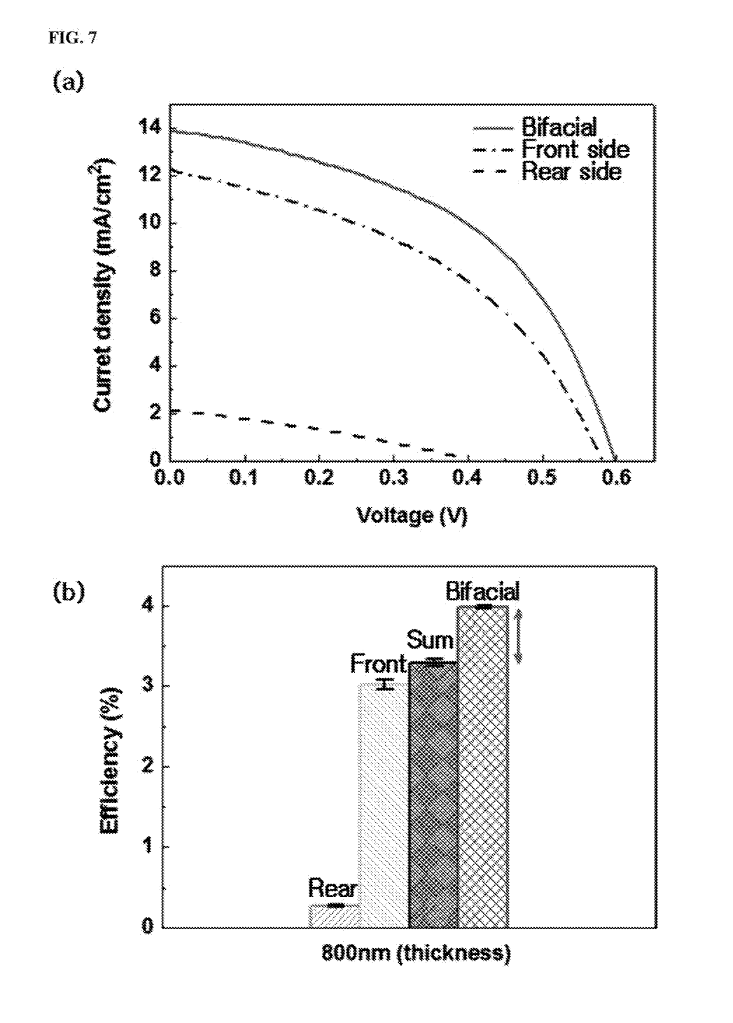

As seen in FIG. 7, the bifacial device (800 nm thick CIGS film) showed much higher solar cell performance than monofacial one (front or rear side was shielded by black tape). This was also consistent irrespective of the devices with different levels of CIGS film thickness. More importantly, additional efficiency gain (˜0.7%) of bifacial device was also obtained (FIG. 7 (b)).

It should be emphasized that such a synergetic efficiency gain of the bifacial solar cell device has not been observed in vacuum deposition based CIGS solar cell devices. One of the distinctive features of the CIGS film prepared by solution coating in the present invention may be its shorter diffusion length than the absorber thickness and the consequent collection loss (FIGS. 3 and 4). The solution processed CIGS film, in general, has poorer crystallinity with more grain-to-grain interfaces (grain boundaries) and grain-to-gas interfaces (pores) in comparison with the vacuum processed film. Thus, the lattice defects including impurity ions as well as two-dimensional defects may act as traps for electronic carriers, leading to a smaller diffusion length and hence the collection loss under device operating conditions. However, in the bifacial solar cell, the photons incident at the rear side act partly as a bias light for the CIGS absorber layer to excite a number of defects present in the solution processed CIGS thin film. This excitation functions to reduce the role of the defects as traps for charges generated by the front side illumination, eventually bringing about an improvement of the solar cell efficiency.

As discussed above, the solution processed chalcopyrite compound film (CuInGaS₂, CIGS) was synthesized on the transparent conducting oxide substrates (tin-doped indium oxide, ITO) aiming at fabrication of the bifacial inorganic thin film solar cells by a low cost and printable method. Simple paste coating method was applied to prepare the CIGS thin films using the methanol based precursor solution under ambient conditions followed by two step heat treatment process (oxidation and sulfurization). According to the solar cell performance of the CIGS solar cell devices with the CIGS thin films of three different thickness (400, 800, and 1200 nm), the solar cell device with the thickest film (1200 nm) resulted in the highest power conversion efficiency for front side illumination (5.61%) while the 800 nm thick film revealed the best solar to electricity conversion performance for rear side illumination (1.01%). In order to mimic outdoor applications, in which sunlight can reach both the front and rear sides of solar cell devices, either the front or rear sides of the bifacial devices were irradiated simultaneously with two solar simulators. Compared to the simple sum of the efficiencies of the front and rear side illumination only, the bifacial illumination resulted in an extra increase of the apparent power conversion efficiency in the range of 0.1˜0.5%, depending on the CIGS film thickness. It was also confirmed that this extra output power acquisition due to bifacial irradiation was not apparently influenced by the light intensity of the rear side illumination, implying that reflected light from the ground (weak light) can be efficiently utilized for improving the overall solar cell efficiency of bifacial devices. This was further confirmed by power conversion efficiency measurement in an outdoor test.

What is claimed is:

1. A thin film solar cell comprising (a) a transparent conducting substrate, (b) an absorber layer formed on the transparent conducting substrate, and (c) a buffer layer, a window layer, and an electrode formed on the absorber layer, wherein the absorber layer is produced by a solution processing method.

2. The thin film solar cell according to claim 1, wherein the solution processing method comprises
(a) dissolving a metal precursor and a polymer binder in a solvent to obtain a precursor paste,
(b) coating the precursor paste on the transparent conducting substrate,
(c) annealing the transparent conducting substrate coated with the precursor paste in air or an oxygen gas atmosphere to obtain a metal oxide thin film, and
(d) annealing the metal oxide thin film in a sulfur gas, a selenium gas or a sulfur/selenium mixed gas atmosphere to obtain a sulfurized or selenized metal oxide thin film.

3. The thin film solar cell according to claim 2, wherein the solvent is selected from water, alcohol, acetone, and mixtures thereof, and the polymer binder is selected from ethyl cellulose, polyvinyl acetate, palmitic acid, polyethylene glycol, polypropylene glycol, polypropylene carbonate, propylenediol, and mixtures thereof.

4. The thin film solar cell according to claim 3, wherein the metal precursor is a mixture of a Cu precursor, an In precursor and a Ga precursor, and the sulfurized or selenized metal oxide thin film is a CIGS thin film.

5. The thin film solar cell according to claim 4, wherein the solution processing method comprises
(a) mixing a first metal precursor, a first organic binder, and a first water-soluble solvent to obtain a first paste,
(b) mixing a second metal precursor, a second organic binder, and a second water-soluble solvent to obtain a second paste,
(c) coating the first paste on the transparent conducting substrate to form a first paste layer,
(d) coating the second paste on the first paste layer to form a second paste layer,
(e) annealing the coated transparent conducting substrate in air or an oxygen atmosphere to obtain a mixed oxide thin film, and
(f) annealing the mixed oxide thin film in a sulfur gas, a selenium gas or a sulfur/selenium mixed gas atmosphere to obtain a sulfide or selenide thin film,
wherein the first metal precursor and the second metal precursor are identical to or different from each other and are each independently a precursor of one or more Group IB metals, a precursor of one or more Group IIIA metals, or a mixture thereof, and the precursor of one or more Group IB metals and the precursor of one or more Group IIIA metals are each independently included in either the first metal precursor or the second metal precursor or both of them.

6. The thin film solar cell according to claim 1, wherein the solution processing method comprises
(a) mixing first metal precursors, a first organic binder, and a first water-soluble solvent to obtain a first paste,
(b) mixing second metal precursors, a second organic binder, and a second water-soluble solvent to obtain a second paste,
(c) coating the first paste on the transparent conducting substrate to form a first paste layer,
(d) coating the second paste on the first paste layer to form a second paste layer,
(e) annealing the coated transparent conducting substrate in air or an oxygen atmosphere to obtain a CIG mixed oxide thin film, and
(f) annealing the CIG mixed oxide thin film in a sulfur gas, a selenium gas or a sulfur/selenium mixed gas atmosphere to obtain a CIGS thin film,
wherein the first metal precursors and the second metal precursors are identical to or different from each other and are each independently two or more kinds of precursors selected from Cu, In and Ga precursors, and the Cu, In and Ga precursors are each independently included in either the first metal precursors or the second metal precursors or both of them.

7. The thin film solar cell according to claim 5 or 6, wherein the first water-soluble solvent and the second water-soluble solvent are identical to or different from each other and are each independently selected from water, alcohol, acetone, and mixtures thereof,
the first organic binder and the second organic binder are identical to or different from each other and are each independently selected from ethyl cellulose, polyvinyl acetate, palmitic acid, polyethylene glycol, polypropylene glycol, polypropylene carbonate, propylenediol, and mixtures thereof.

8. The thin film solar cell according to any one of claims 1 to 6, wherein the transparent conducting substrate is made of at least one material selected from indium tin oxide, fluorine-doped indium tin oxide, glass, and transparent conducting polymers, or is a transparent non-conducting substrate coated with at least one material selected from indium tin oxide, fluorine-doped indium tin oxide, glass, and transparent conducting polymers.

9. The thin film solar cell according to claim 1, wherein the absorber layer has a thickness 1 to 10 times larger than 200±20 nm.

10. The thin film solar cell according to claim 9, wherein the thickness of the absorber layer is 400±20 nm.

11. The thin film solar cell according to claim 9, wherein the thickness of the absorber layer is 800±20 nm.
